(19) United States
(12) Patent Application Publication
(10) Pub. No.: US 2007/0023282 A1
(43) Pub. Date: Feb. 1, 2007

(54) Deflection magnetic field type vacuum arc vapor deposition device

(76) Inventor: Yasuo Murakami, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/554,928

(22) PCT Filed: Jun. 2, 2004
(86) PCT No.: PCT/JP04/08018

§ 371 Date: Jul. 10, 2006

(30) Foreign Application Priority Data
Jun. 13, 2003 (JP) 2003-169754

(51) Int. Cl. C23C 14/00

(52) U.S. Cl. 204/298.41

(57) ABSTRACT

A vacuum arc vapor deposition apparatus of a deflection field type includes a plurality of vapor deposition units (UN1, UN2) each including a vapor source (3, 3′) and a curved filter duct (4, 4′) provided with deflection field forming coils (400, 42 or 42′). The ducts (4, 4′) have duct ends opposed to the deposition target holder (2) and formed together to provide a common duct end (40). The vapor source (3, 3′) is arranged on the other end (41, 41′) of each duct. The coil (400) is arranged for the common duct end (40), and one magnetic field forming coil (42, 42′) is arranged for each of the ducts. An adjusting device (motors m1, m2 and drive device PC, motors M1, M2 and drive device PC1, motors M1′, M2′ and drive device PC1′) for adjusting a state of arrangement is arranged for each coil. This vacuum arc vapor deposition apparatus can form a thin film of good quality having a desired structure on the deposition target with good productivity.

### TECHNICAL FIELD

The present invention relates to a vacuum arc vapor deposition apparatus, which can be used for depositing thin films on subjects or works such as automobile parts, machine parts, tools or dies for the purpose of, e.g., improving at least one of wear resistance, sliding property, corrosion resistance and others.

### BACKGROUND ART

According to a vacuum arc vapor deposition apparatus, vacuum arc discharge is caused between an anode and a cathode to vaporize a cathode material by the arc discharge in a vacuum atmosphere, and plasma containing the ionized cathode material is produced to provide the ionized cathode material onto a deposition target or work so that a thin film is deposited on the deposition target. Vacuum arc discharge is caused between the anode and cathode to ionize the cathode material in a portion of the apparatus, which is generally referred to as a vapor source or a vacuum arc vapor source. The vacuum arc vapor deposition apparatus is superior in deposition rate and film productivity to a plasma CVD device and others.

A vacuum arc vapor deposition apparatus of a deflection field type has been known as a kind of such vacuum arc vapor deposition apparatus. The vacuum arc vapor deposition apparatus of the deflection field type includes the foregoing vapor source as well as a curved filter duct, in which a permanent magnet or a coil for producing a magnetic field produces a deflecting magnetic field (i.e., magnetic field for deflection) for causing flight of an ionized cathode material of the vapor source toward a holder holding the deposition target.

According to the vacuum arc vapor deposition method, rough particles, which are referred to as “macro-particles” or “droplets”, may occur when the arc discharge vaporizes the cathode. Such rough particles may fly and adhere to the deposition target, and thereby the rough particles may lower surface smoothness of a film formed on the deposition target as well as adhesivity of the film to the deposition target.

The curved filter duct, in which the foregoing deflecting magnetic field is formed, can selectively guide the ionized cathode material, i.e., charged particles to the deposition target owing to the deflecting magnetic field, which deflects the ionized material along the duct. Also, the magnetic field does not deflect the rough particles because the rough particles are electrically neutral, and have extremely large mass even if these are charged. Therefore, the rough particles impinge on the inner wall of the curved duct so that flight and adhesion of the rough particles to the deposition target are suppressed. Thereby, a thin film of a good quality can be formed on the deposition target.

Such vacuum arc vapor deposition apparatuses provided with the above filter ducts have also been proposed that can form a thin film over a large area with good productivity, or that a composite film can be formed. For example, Japanese Laid-Open Patent Publication No. 2001-59165 (JP 2001-59165 A) has disclosed a structure, in which a plurality of vapor sources are arranged for one filter duct having a square section or the like so that a film having high surface smoothness and high thickness uniformity can be formed over a large area.

Japanese Laid-Open Patent Publication No. H9-217141(JP 1997-217141 A) has disclosed a structure, in which two filter ducts each provided with a vapor source, which includes a cathode made of a material different from that of the other, are connected to different positions on a deposition container wall (deposition chamber wall), respectively, so that fine particles produced from each vapor source are provided to a deposition target to form a fine particle dispersed film (composite film). More specifically, for example, one of the vapor sources has a cathode containing titanium, and the other has a cathode made of nickel. An arc discharge voltage is alternately applied in a pulse-like form to these vapor sources. Thereby, the apparatus forms, in a nitrogen gas atmosphere, a fine particle dispersed film, which is formed of hard fine particles of titanium nitride and metal fine particles of nickel.

As another vacuum arc vapor deposition apparatus with a filter duct. Japanese Laid-Open Patent Publication No. 2002-294433 (JP 2002-294433 A) has disclosed the following. Uniformity in thickness distribution of a film formed on a deposition target surface may deteriorate due to drift of plasma in a magnetic field produced by a field producing coil. More specifically, if the-field coil is always supplied with a current in a constant direction, the drift of the plasma in the magnetic field deviates or shifts a peak of the film thickness of the film formed on the deposition target in a constant direction. This may lower the uniformity in film thickness distribution. For preventing such lowering, the direction of the current flowing through the field forming coil is repetitively inverted during the deposition according to the disclosure of the above reference.

In general, the thin films having various structures can be formed on the deposition targets. For example, a thin film may be entirely formed of a uniform material. Also, a composite film may be formed of several kinds of dispersed fine particles as described above. Further, a thin film may be formed of a base layer and a desired layer formed over it, a compound film may be formed of two or more kinds of elements, or a thin film made of a predetermined material may contain another element added thereto.

For forming the thin film having the base layer, the compound film, the thin film containing an added element or the like by the vacuum arc vapor deposition apparatuses with good productivity, it is necessary to employ a plurality of vapor sources, which include cathodes of different materials, respectively, similarly to the case of forming the foregoing fine particle dispersed film.

Such multiple kinds of vapor sources may be formed of a plurality of vapor sources provided for one filter duct, as is disclosed in the Japanese Laid-Open Patent Publication No. 2001-59165 (JP 2001-59165 A) already described. In the structure having the multiple kinds of vapor sources respectively arranged in different positions of one filter duct, however, it is practically difficult to form the above film on the deposition target arranged in a predetermined position because the ionized cathode material produced from each vapor source takes a path different from that of another ionized cathode material in the same filter duct.

Accordingly, for forming the above thin film over the deposition target in the predetermined position, the filter ducts corresponding in number to the types of the vapor sources must be arranged in different positions on a deposition container wall, respectively, as disclosed in the Laid-Open Patent publication No.H9-217141.

When forming, e.g., the compound film, however, the several kinds of ionized cathode materials fly from different positions to the deposition target in the constant position so that a film having multiple layers, which are made of the different cathode materials, respectively, is liable to be formed instead of the intended compound film. In addition to the formation of the compound film, the formation of the thin film containing the base layer and the formation of the thin film containing an additional element may suffer form such a problem that the film quality and/or film thickness of the thin film may not be uniform because the several kinds of ionized cathode materials fly from different positions to the deposition target in the constant position. Further, the filter ducks, which correspond in number to the vapor sources, are connected to different positions on the deposition container wall so that this structure impedes reduction in sizes of the vacuum arc vapor deposition apparatus.

Japanese Laid-Open Patent Publication No. 2001-521066(JP 2001-521066 A) has disclosed a vacuum arc vapor deposition apparatus, in which two curved magnetic filter ducts are arranged such that filter duct ends opposed to a deposition target held on a holder in a deposition container are formed of a common end, and vapor sources are arranged on the other ends spaced from each other, respectively. This kind of vacuum arc vapor deposition apparatus can have a compact structure. Further, the ionized cathode materials produced from different vapor sources fly from one position, i.e., the common duct end. Accordingly, in any one of the cases of forming, e.g., the thin film containing the base layer, the compound film, and the thin film containing an additional element, it can be seemed that the thin film can be formed in a desired stated, as compared with the case, in which the two or more filter ducts are connected to different positions on the deposition container, respectively.

According to the study by the inventors, however, the following problem is still to be overcome in the vacuum arc vapor deposition apparatus of the common duct end type.

FIG. 6 shows a basic structure of a vacuum arc vapor deposition apparatus disclosed in the Japanese Laid-open Patent publication No. 2001-521066. As shown in FIG. 6, a holder 92 is arranged in a predetermined position within a deposition container 91 for holding a deposition target s. Two curved filter ducts 93 and 94 are connected to one position on the deposition container 91, which is opposed to the holder 92.

These filter ducts 93 and 94 have a common portion 90, which is shared between the filter ducts 93 and 94 for connection to the deposition container 91, and is opposed to the holder 92. The filter ducts 93 and 94 have opposite duct ends, which are spaced from each other. Vapor sources 95 and 96 containing cathodes, which are made of different materials, are arranged on these spaced ends, respectively. A permanent magnet or a coil 97 is arranged around the filter duct 93 for forming a magnetic field, and a permanent magnet or a coil 98 is arranged around the filter duct 94 for forming a magnetic field. A permanent magnet or a coil 99 is arranged around the common duct end 90 for forming a magnetic field for use by both the ducts 93 and 94.

The ionized cathode material produced from the vapor source 95 can fly from the duct 93 through the common duct end 90 owing to the deflection field formed by the magnets 97 and 99. The ionized cathode material produced from the other vapor source 96 can fly from the duct 94 through the common duct end 90 owing to the deflection field formed by the magnets 98 and 99.

In theory, therefore, a compound film made of different materials can be formed on the deposition target s by simultaneously operating the two vapor sources. Also, the composite film of the fine particle dispersed type or the multi-layer structure film can be formed by alternately and repetitively operating the two vapor sources. Further, the following manners may be implemented. One of the vapor sources is operated to form the base layer on the deposition target s, and thereafter only the other vapor source is operated to form a desired film on the base layer. One of the vapor sources operates to add an additional element to the film, which is being formed by using the other vapor source. Only one of the vapor sources is used to form a film formed of the same material on the deposition target s.

However, if it is practically attempted to form a compound film or a composite film by the above apparatus, the deflection fields in the filter ducts 93 and 94 mutually affect so that flows 950 and 960 of the ionized cathode materials, which are produced from the vapor sources 95 and 96, respectively, may not join together to form a flow directed toward the deposition target s on the holder, but may be directed in different directions after or without crossing, respectively, Consequently, it may be difficult to form the desired compound film or the like on the deposition target s. Even in the case of forming, e.g., the film including the base layer or the film containing an additional element, it may be difficult to concentrate finally the respective ionized cathode material onto the deposition target s on the holder.

Accordingly, it is an object of the invention to provide a vacuum arc vapor deposition apparatus of a deflection field type, which includes a plurality of vapor deposition units each including a vapor source configured to vaporize and ionize a cathode material by a vacuum arc discharge between a cathode and an anode, and a curved filter duct provided with a deflection field forming member providing the ionized cathode material produced from the vapor source toward a holder holding a deposition target for forming a film containing a component element of the cathode material on the deposition target. The curved filter ducts of the plurality of vapor deposition units have duct ends opposed to the holder and formed together to provide a common duct end. At least one of the vapor sources is arranged on the other end of each of the filter ducts. This type of apparatus may also be referred to as “the vacuum arc vapor deposition apparatus of the deflection field type and the common duct end type”, and can form a thin film of good quality having a desired structure on the deposition target with good productivity.

### DISCLOSURE OF THE INVENTION

The inventors have earnestly conducted research for achieving the foregoing object, and found the following to complete the invention.

A state of arrangement of the deflection magnetic field forming member arranged at the filter duct can be adjusted by adjusting, e.g., the position of the member in the direction of extension of the duct, the angular position of the member with respect to the duct and/or a combination of such positions, and thereby it is possible to change characteristics (directions of lines of magnetic force and others) of magnetic field formed in the duct by the deflection magnetic field forming member. Thereby, it is possible to control the direction of flight of the ionized cathode material in the duct.

Accordingly, in connection with one, some or all of the plurality of filter ducts in the vacuum arc vapor deposition apparatus of the deflection field type and the common duct end type, the arrangement state of one, some or all of the deflection magnetic field forming members, which are provided for the filter duct(s), can be adjusted so that the flows of the ionized cathode materials produced from the respective vapor sources of the plurality of vapor deposition units can be joined together in the common duct end of the plurality of filter ducts, and thereby can be directed toward the deposition target on the holder. Thereby, even if the film to be formed is a compound film or the like, it is possible to form the film having good quality and desired structure on the deposition target with good productivity.

Based on the above findings, the invention provides a vacuum arc vapor deposition apparatus of a deflection field type, which includes a plurality of vapor deposition units each including at least one vapor source configured to vaporize and ionize a cathode material by a vacuum arc discharge between a cathode formed of the cathode material and an anode, and a curved filter duct provided with at least one deflection magnetic field forming member providing the ionized cathode material produced from the vapor source toward a holder holding a deposition target for forming a film containing a component element of the cathode material on the deposition target. The curved filter ducts of the plurality of vapor deposition units have duct ends opposed to the holder and formed together to provide a common duct end. At least one vapor source is arranged on the other end of each of the filter ducts.

The above apparatus includes a magnetic field forming member adjusting device adjusting a state of arrangement of at least one of the deflection magnetic field forming member provided for at least one of the filter ducts of the plurality of vapor deposition units with respect to the filter duct for controlling the magnetic field.

### BRIEF DESCRIPTION OF THE DRAWINGS

FIG. 1 shows a schematic structure of an example of a vacuum arc vapor deposition apparatus of a deflection field type according to the invention.

FIG. 2 is a sectional view of a common end of two filter ducts in the apparatus shown in FIG. 1.

FIG. 3(A) shows a structure of one of vapor sources, and FIG. 3(B) shows the other vapor source.

FIG. 4 is a block diagram fragmentarily showing electric circuits of the apparatus shown in FIG. 1.

FIG. 5 schematically shows a structure of another example of the vacuum arc vapor deposition apparatus of the deflection field type.

FIG. 6 shows a basic structure of an example of a conventional vacuum arc vapor deposition apparatus.

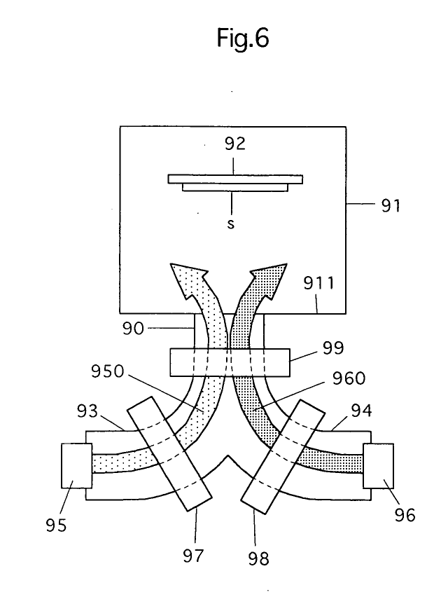

### DESCRIPTION OF THE PREFERRED EMBODIMENTS

A vacuum arc vapor deposition apparatus of a deflection field type according to an embodiment of the invention includes a plurality of vapor deposition units each including a vapor source configured to vaporize and ionize a cathode material by a vacuum arc discharge between a cathode formed of the cathode material and an anode, and a curved filter duct provided with one or more deflection magnetic field forming members providing the ionized cathode material produced from the vapor source toward a holder holding a deposition target for forming a film containing a component element of the cathode material on the deposition target.

The curved filter ducts of the plurality of vapor deposition units have duct ends opposed to the holder and formed together to provide a common duct end. At least one vapor source is arranged on the other end of each of the filter ducts.

The above apparatus further includes a magnetic field forming member adjusting device adjusting a state of arrangement of at least one of the deflection magnetic field forming member provided for at least one of the filter ducts of the plurality of vapor deposition units with respect to the filter duct for controlling the magnetic field.

The deflection magnetic field forming member may be formed of a permanent magnet, a magnetic field forming coil forming a magnetic field when energized, or a combination of these magnet and coil. In any one of the above structure, it is preferable that the deflection magnetic field forming member is arranged around the duct.

Typically, the magnetic field forming member adjusting device may be configured to adjust a position, in the direction of extension of the filter duct, of the deflection magnetic field forming member having the arrangement state to be adjusted by the magnetic field forming member adjusting device and forming a magnetic field in the filter duct, and/or to adjust an angular position of the deflection magnetic field forming member with respect to the duct.

Typically, the filter duct may have a rectangular section, although not restricted thereto. In the case where the duct has the rectangular section, the angular position of the deflection magnetic field forming member adjusted by the adjusting device with respect to the duct may be adjusted around an axis substantially perpendicular to a pair of opposed side surfaces among four side surfaces of the duct, and/or may be adjusted around another axis substantially perpendicular to the above axis (i.e., around the axis substantially perpendicular to the other pair of opposed side surfaces).

In the structure having the plurality of deflection magnetic field forming members on the each filter duct, one of the deflection magnetic field forming members may be shared with one of the deflection magnetic field forming members provided for the different filter duct. The deflection magnetic field forming member thus shared may be arranged at the foregoing common duct end.

Typically, the deflection magnetic field forming member shared among the plurality of filter ducts is arranged on the duct end opposed to the holder shared among the plurality of filter ducts, and also, the deflection magnetic field forming members are arranged on the portions of the filter ducts each spaced from the other filter ducts, respectively.

In the vacuum arc vapor deposition apparatus having any one of the above structures, the magnetic field forming member adjusting device can adjust the arrangement state of the corresponding deflection magnetic field forming member with respect to the filter duct to control characteristics (e.g., directions of lines of magnetic force) of the magnetic field formed in the duct by the magnetic field forming member, and thereby to control a direction of flight of the ionized cathode material produced from the vapor source provided for the duct so that the ionized cathode material can be supplied from the common duct end toward the deposition target on the holder.

When the ionized cathode material(s) are provided from the one or more other filter ducts, the arrangement state of the magnetic field forming member arranged in a variable state may be adjusted such that the ionized cathode material provided from the filter duct having the adjustable magnetic field forming member may join the flow of the other ionized cathode material(s), and thereby joined flows of the ionized cathode materials are directed toward the deposition target.

For joining the flows of the ionized cathode materials provided from the plurality of filter ducts, and directing the joined flows toward the deposition target on the holder from the common duct end, sufficient control may not be achieved only by adjusting the arrangement state of the one magnetic field forming member of the one duct. In this case, an adjusting device may be arranged for another magnetic field forming member of the same one duct for adjusting the arrangement state thereof. Further, the adjusting device may be arranged for each of the one or more magnetic field forming members of the one or more ducts for adjusting the arrangement state of the magnetic field forming member with respect to the duct.

Even in the case where it is not required to join the flows of the ionized cathode materials provided from the plurality of filter ducts together, it may be difficult in each filter duct to direct the flow of the ionized cathode material from the common duct end toward the deposition target. In this case, the adjusting device for the arrangement state may be arranged for each of the one or more deflection magnetic field forming members in each of the filter ducts.

For example, the deflection magnetic field forming member to be shared among the plurality of filter ducts may be arranged for the common duct end of the plurality of filter ducts opposed to the holder, and also, the deflection magnetic field forming members may be arranged for the portions of the plurality of filter ducts each spaced from the other filter duct(s), respectively. In this case, the magnetic field forming member adjusting device may be provided for each of the deflection magnetic field forming members.

In any one of the above cases, the structure, in which the arrangement states of the one or more magnetic field forming members of each of the one or more filter ducts are adjusted with respect to the duct(s), can join the flows of the ionized cathode materials produced from the respective vapor sources of the plurality of vapor deposition units together at the common duct end of the plurality of filter ducts, and can direct the flows toward the deposition target on the holder. Thereby, even if a compound film or the like is to be formed, the film having the desired structure can be formed on the deposition target with good quality and good productivity.

The vacuum arc vapor deposition apparatus can simultaneously use the two or more vapor sources, and thereby can form the compound film made of different materials on the deposition target. By using them alternately, it is possible to form the composite film of the fine particle dispersed type or the film of the multi-layer structure made of different materials. One of the vapor sources may be used to form the base layer on the deposition target, and thereafter another vapor source may be used instead of the former vapor source to form a desired film on the base layer. Alternatively, one of the vapor sources may be used to form a film, and another vapor source may be used to add a different element to the film, which is being formed by the one of the vapor sources. Only the vapor source of any one of the vapor deposition units may be used to form the film made of the same material on the deposition target.

The apparatus may be configured as follows for suppressing such a situation that drift of plasma in the magnetic field formed by the deflection magnetic field forming member deteriorates the uniformity in film thickness distribution of the film formed on the surface of the deposition target. One or more of the deflection magnetic field forming members are formed of field forming coils to be energized by a field formation power supply device to form a deflection field (i.e., magnetic field for deflection), and the field formation power supply device may be a power supply device cyclically inverting a direction of a current in at least one of the field forming coil (s).

The apparatus may be configured as follows, e.g., for forming the layered film formed of layers of different materials, for forming, e.g., the film containing a different element added to a predetermined portion in the direction of film thickness, for preventing flight of the ionized cathode material produced from the vapor source to the deposition target when necessary.

Thus, one or more of the deflection magnetic field forming members are formed of magnetic field forming coils forming the deflection magnetic field when energized by a field formation power supply device. The field formation power supply device may be a power supply device capable of turning on/off the power supply to each of the magnetic field forming coils independently of the others. By deenergizing the magnetic field forming coil, it is possible to prevent flight of the ionized cathode material to the deposition target.

For the similar purpose, at least one of the vapor deposition units may be provided with a shut-off member being movable between a closing position for shutting off a passage of the ionized cathode material in the filter duct in the vapor deposition unit and an opening position for opening the passage.

For producing the arc discharge between the anode and the cathode of the vapor source in the vacuum arc vapor deposition apparatus, a trigger electrode for arc discharging is opposed to a discharging surface of the cathode, and a voltage is applied across the cathode and the trigger electrode. Further, the trigger electrode is brought into contact with the discharging surface of the trigger electrode, and then is spaced therefrom to cause the arc discharge so that the arc discharge is induced between the anode and the cathode.

Depending on the cathode material, however, the vacuum arc discharge may often cease. Whenever the arc discharge ceases, it is necessary to restart the film deposition by inducing the vacuum arc discharge between the anode and the cathode with a trigger electrode for inducing the arc discharge.

However, the arc discharge is unstable at the time of so-called “arc ignition”, i.e., when the trigger electrode induces the vacuum arc discharge between the anode and the cathode. Therefore, when the arc ignition is repeated in the film depositing process, this lowers the film quality.

Accordingly, such means has been required that can produce a film of good quality without excessively increasing the time from start of the film deposition to the completion even when the trigger electrode induces the vacuum arc discharge in response to the ceasing or turn-off of the vacuum arc discharge during the film deposition on the deposition target.

Accordingly, the following may be employed.

At least the plurality of vapor deposition units to be used simultaneously among the plurality of vapor deposition units are provided with the magnetic field forming coils serving as the deflection magnetic field forming members and forming the deflection magnetic field when being energized by a field formation power supply device, and are also provided with detectors detecting on/off of the arc discharge in the vapor sources. The field formation power supply device is configured to deenergize the magnetic field forming coils of the vapor deposition units to be used simultaneously when at least one of the detectors in the vapor deposition units to be used simultaneously detects the ceasing of the arc discharge, and to allow the energizing of the magnetic field forming coils upon elapsing of a time required for attaining the stable arc discharge in all the vapor sources of the vapor deposition units to be used simultaneously after all the detectors in the vapor deposition units to be used simultaneously detected the arc discharge.

For similar reasons, the following may be employed.

Each of the vapor deposition units to be used simultaneously among the plurality of vapor deposition units may be provided with a shut-off member being movable between a closing position for shutting off a passage of the ionized cathode material in the filter duct in the vapor deposition unit and an opening position for opening the passage, a drive device selectively driving the shut-off member to the closing position and the opening position, and a detector detecting on/off of the arc discharge in the vapor source. The drive device of the shut-off member in each of the vapor deposition units is configured to operate under control of a control unit. When the plurality of vapor deposition units to be used simultaneously are simultaneously used, the control unit controls the drive devices such that the shut-off members of the filter ducts of the vapor deposition units to be used simultaneously are located in the closing position when at least one of the detectors in the vapor deposition units to be used simultaneously detects the ceasing of the arc discharge, and to locate the shut-off members in the opening position upon elapsing of a time required for attaining the stable arc discharge in all the vapor sources of the vapor deposition units to be used simultaneously after all the detectors in the vapor deposition units to be used simultaneously detected the arc discharge.

The detector detecting the on/off of the arc discharge in the vapor source may be a current detector detecting a discharge current based on the vacuum arc discharge, or may be a voltage detector detecting a voltage applied to the cathode. In the structure including the current detector, when it does not detect a current value representing that the vacuum arc discharge is on, it can be determined that the vacuum arc discharge is off. When the detector detects a current value representing that the vacuum arc discharge is on, it can be determined that the vacuum arc discharge is on. In the structure including the voltage detector, when the voltage detector does not detect a voltage value representing that the vacuum arc discharge is on, it can be determined that the vacuum arc discharge is off. When the voltage detector detects a voltage value representing that the vacuum arc discharge is on, it can be determined that the vacuum arc discharge is on.

The foregoing time required for attaining the stable arc discharge in the vapor sources is variable depending on the material of the cathode, specific structures of the vacuum arc vapor deposition apparatus and others, and therefore can be determined in advance, e.g., based on experiments or the like.

For the control of the film structure and composition as well as other purpose, a power supply device applying a pulse voltage may be employed as at least one of the arc power supply devices, which applies a voltage across the cathode and the anode of the vapor source in each of the vapor deposition units for causing the arc discharge. This power supply device may be configured to control at least one of a magnitude of the pulse voltage, a pulse width and a duty.

At least one of the vapor deposition units may be provided with the plurality of vapor sources.

An example of a vacuum arc vapor deposition apparatus of the deflection field type will now be described with reference to the drawings.

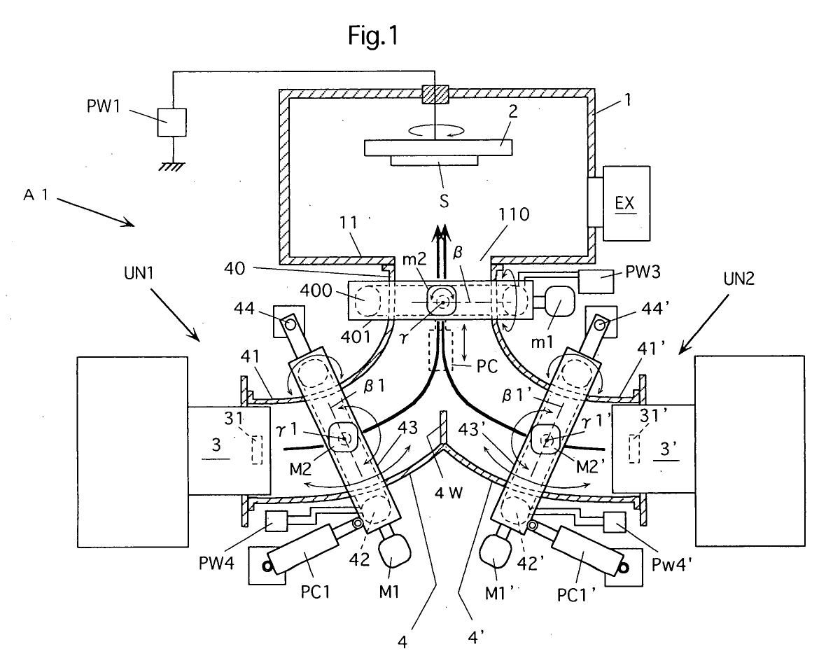

FIG. 1 shows a schematic structure of an example A1 of the vacuum arc vapor deposition apparatus of the deflection field type. The vacuum arc vapor deposition apparatus A1 shown in FIG. 1 includes a deposition container (chamber) 1, in which a holder 2 is arranged for supporting a deposition target S or work, which takes the form of a substrate in this embodiment. The holder 2 is connected to a power source PW1, which applies a bias voltage to the deposition target S held by the holder 2 during film deposition.

The container 1 is connected to an exhaust device EX, which can attain an intended vacuum state in the container 1. Two vapor deposition units UN1 and UN2 are connected to one position of a container wall 11.

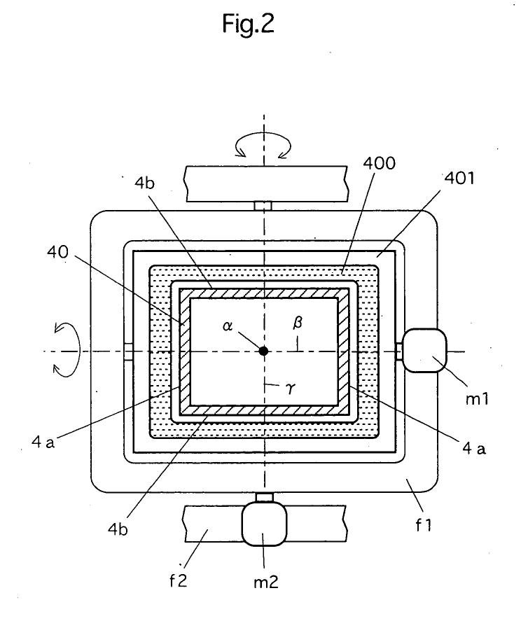

The vapor deposition unit UN1 includes a curved filter duct 4 and a vapor source 3. The filter duct 4 has an end 40 opposed to the holder 2, which is connected to a wall around a rectangular opening 110 formed in the foregoing one position. The vapor source 3 is arranged on the other end 41 of the duct 4. The duct 4 is curved by nearly about 90 degrees, and has a rectangular section (see FIG. 2).

A magnetic field forming coil 400 is arranged around the end 40 of the duct 4 near the deposition container 1. Another magnetic field forming coil 42 is arranged around a portion of the duct 4 near the other end 41. The coil 400 is carried by a frame 401, and the coil 42 is carried by a frame 43. Power sources PW3 and PW4 can energize the coils 400 and 42, respectively, so that a deflection field (i.e., a magnetic field for deflection) can be formed in the duct 4.

As shown in FIGS. 1 and 2, the coil frame 401 is carried by a first member f1 for rotation in opposite directions around an axis β, which is perpendicular to opposed side surfaces 4a of the duct 4, and is perpendicular to a central axis α of the duct 4 extending along its length. A rotary motor M1 carried on the member f1 can drive and rotate the coil frame 401 around the axis β in both the directions. Thereby, the angular position of the coil 400 carried by the coil frame 401 is adjustable around the axis β.

The coil frame 401 is carried together with the first member f1 and motor M1 by a second member f2 for rotation in opposite directions around an axis γ, which is perpendicular to the other opposed side surfaces 4b of the duct 4, and is perpendicular to the central axis α of the duct 4 extending along its length. A rotary motor M2 carried on the member f2 can drive and rotate the coil frame 401 around the axis γ in both the directions. Thereby, the angular position of the coil 400 is adjustable around the axis γ.

Further, a reciprocation drive device PC (see FIG. 1) in a stationary position can adjust the position of the coil 400, the frame 401 carrying the coil 400 as well as motors M1 and M2 as a whole in the direction of the duct center axis α (i.e., in the direction of extension of the duct). Thus, the position of the coil 400 in the vertical direction in FIG. 1 can be adjusted in this example. The motors M1 and M2 as well as the device PC and others form a coil adjusting device for the coil 400.

Similarly to the rotary mechanism for the coil frame 401, the coil frame 43 carrying the coil 42 is carried by a first member (not shown) for rotation in opposite directions around an axis β1, which is perpendicular to the opposed side surfaces 4a of the duct 4, and is perpendicular to the center axis α of the duct 4, and can be driven to rotate in the opposite directions around the axis β1 by a rotary motor M1 carried by the first member. Thereby, the angular position of the coil 42 carried by the coil frame 43 can be adjusted around the axis β1.

The coil frame 43 is carried together with the first member (not shown) and the motor M1 carried thereby by a second member (not shown) for rotation in opposite directions around an axis γ1, which is perpendicular to the other opposed side surfaces 4b of the duct 4, and is perpendicular to the central axis α of the duct 4 extending along its length. A rotary motor M2 carried on the second member can drive and rotate the coil frame 43 around the axis γ1 in both the directions. Thereby, the angular position of the coil 42 is adjustable around the axis γ1.

The coil 42, the frame 43 carrying it and the motors M1 and M2 is swingable as a whole in a lengthwise direction (i.e., direction of extension) of the duct 4 around a support axis 44 located in a stationary position, and a reciprocation drive device PC1 can adjust the position thereof in this lengthwise direction. The motors M1 and M2 as well as the device PC1 and others form a coil adjusting device for the coil 42.

The other vapor deposition unit UN2 includes a curved filter duct 4′ and a vapor source 3′. The end 40 of the filter duct 4′ is formed to serve also as the end 40 of the filter duct 4 in the vapor deposition unit UN1. Therefore, the duct 4′ is likewise connected to the peripheral wall portion of the opening 110 in the container wall, and is opposed to the holder 2. A vapor source 3′ is arranged on the other end 41′ of the duct 4′. The duct 4′ is curved by nearly 90 degrees, is horizontally symmetrical to the duct 4, and has a rectangular section (see FIG. 2). A partition 4W is arranged in a boundary position substantially between the joined portions of the ducts and the separated portions of the ducts for preventing direct opposing of the vapor sources 3 and 3′.

The duct 4′ is provided with the magnetic field forming coil 400, which is shared with the duct 4, is also provided with a magnetic field forming coil 42′ arranged around a portion near the other end 41′ neighboring to the vapor source 3′, similarly to the case of the duct 4. A frame 43′ carries the coil 42′. Power sources PW3 and PW4′ energize the coils 400 and 42′ to form the deflection field (i.e., the magnetic field for deflection) in the duct 4′, respectively. similarly to the rotary mechanism for the coil frame 401, the coil frame 43′ is carried by a first member (not shown) for rotation in opposite directions around an axis β1′, which is perpendicular to the opposed side surfaces of the duct 4′, and is perpendicular to the center axis of the duct 4′, and can be driven to rotate in the opposite directions around the axis β1′ by the rotary motor M1′ carried by the first member. Thereby, the angular position of the coil 42′ carried by the coil frame 43′ can be adjusted around the axis β1′.

The coil frame 43′ is carried together with the first member (not shown) and the motor M1′ carried thereby by a second member (not shown) for rotation in opposite directions around an axis γ1′, which is perpendicular to the other opposed side surfaces of the duct 4′, and is perpendicular to a central axis of the duct 4′ extending along its length. A rotary motor M2′ carried on the second member can drive and rotate the coil frame 43′ around the axis γ1′ in both the directions. Thereby, the angular position of the coil 421 is adjustable around the axis γ1′.

The coil 42′, the frame 43′ carrying it and the motors M1′ and M2′ is swingable as a whole in a lengthwise direction (i.e., direction of extension) of the duct 4′ around a support axis 44′ located in a stationary position, and a reciprocation drive device PC1′ can adjust the position thereof in this lengthwise direction. The motors M1′ and M2′ as well as the device PC1′ and others form a coil adjusting device for the coil 42′.

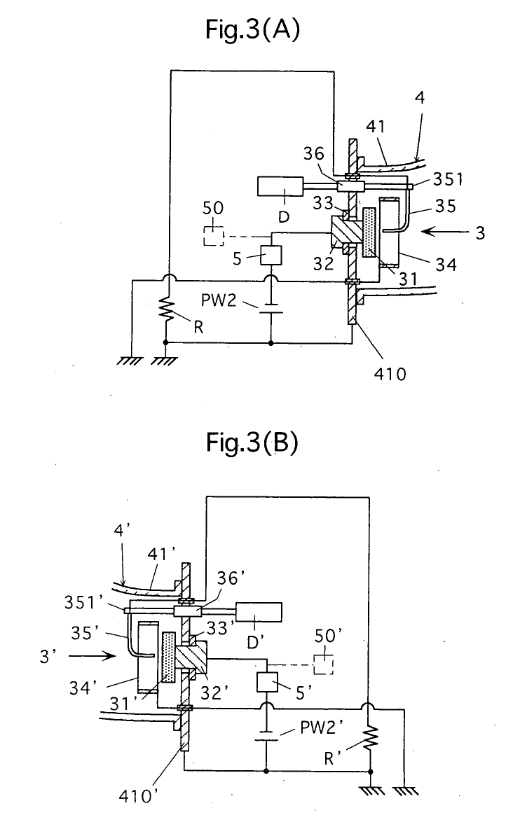

FIG. 3(A) shows a structure of the vapor source 3, and FIG. 3(B) shows a structure of the vapor source 3′. The vapor source 3 (3′) includes a cathode 31 (31′) as shown in FIG. 3(A) or 3(B). The cathode 31 (31′) arranged in the duct is carried by an electrically conductive cathode support 32 (32′) loosely fitted into a central hole in a grounded wall plate 410 (410′), which is attached to the end 41 (41′) of the filter duct 4 (4′). The cathode support 32 (32′) is fixed to the wall plate 410 (410′) via an insulating member 33 (33!).

The cathode 31 (31′) is made of a material selected depending on the film to be formed. In a region of the duct formed inside the wall plate 410 (410′), a cylindrical anode 34 (34′) is opposed to the cathode 31 (31′), and a rod-like trigger electrode 35 (35′) is arranged inside the anode, and is opposed to a central portion of an end surface (discharging surface) of the cathode 31 (31′). The anode 34 (34′) is grounded.

The trigger electrode 35 (35′) extends outward through an opening of the anode 34 (34′) remote from the cathode 31 (31′), and is carried by a support rod 351 (351′). The support rod 351 (351′) is connected to a reciprocative linear drive device D (D′) outside the wall plate 410 (410′) through a so-called feed-through device 36 (36′) arranged on the wall plate 410. The device D (D′) can bring the trigger electrode 35 (35′) into contact with the cathode 31 (31′), and can also space it from the cathode 31 (31′). The feed-through device 36 (36′) can sealingly isolate the inner and outer spaces of the wall plate 410 (410′) from each other, but allows reciprocation of the rod 351 (351′).

The vapor source 3 (3′) further includes an arc power source PW2 (PW2′), which is connected to the cathode 31 (31′) and others for applying an arc discharge voltage across the cathode 31 (31′) and the anode 34 (34′), and applying a trigger voltage across the cathode 31 (31′) and the trigger electrode 35 (35′) to induce the arc discharge between the cathode 31 (31′) and the anode 34 (34′). The trigger electrode 35 (35′) is grounded via a resistance R (R′) for preventing flow of the arc current. A current detector 5 (5′) for detecting a discharge current based on the vacuum arc discharge is connected to a line between the arc power source PW2 (PW2′) and the cathode support 32 (32′). As will be described later, a voltage detector 50 (50′) may be employed instead of the current detector.

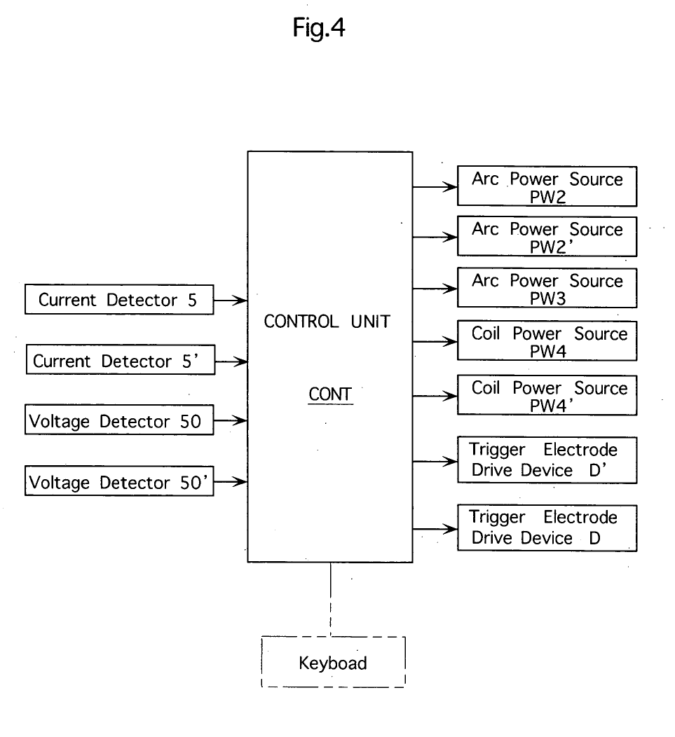

FIG. 4 is a block diagram showing a part of electric circuits in the apparatus A1. As shown in this block diagram, a control unit CONT is connected to the arc power sources PW2 and PW2′, coil power sources PW3, PW4 and PW4′, and trigger electrode drive devices D and D′. The current detectors 5 and 5′ (or voltage detectors 50 and 50′) are also connected to the control unit CONT. As will be described later, the control unit CONT controls on/off of the power sources. However, the coil power sources PW3, PW4 and PW4′ may be controlled independently of the other power sources such that the on/off thereof is controlled to control the magnetic field forming coil corresponding to the power source thereof. In any one of the above cases, it can be considered that the power sources PW3, PW4 and PW4′ as well as the control unit CONT form the magnetic field formation power supply device for the magnetic field forming coils.

The vacuum arc vapor deposition apparatus A1 can form the film by using only one of the vapor sources. In this case, the control unit CONT determines that the vacuum arc discharge is off when the current detector 5 or 5′ does not detect a predetermined discharge current value representing the on state of discharge. When the detector 5 or 5′ detects the predetermined discharge. current value, the control unit CONT determines that the vacuum arc discharge is on.

When control unit CONT determines that the vacuum arc discharge is off, it shuts off the power supply from the power sources PW3 and PW4 (or PW3 and PW4′) to the magnetic field forming coils 400 and 42 (or 400 and 42′), and instructs the trigger electrode drive device D (or D′) to drive the trigger electrode 35 (or 35′) to induce the vacuum arc discharge.

When control unit CONT determines that the vacuum arc discharge is on when the current detector 5 (or 5′) detects a predetermined discharge current value representing the on state of the vacuum arc discharge. The control unit CONT energizes all the magnetic field forming coils 400 and 42 (or 400 and 42′) after elapsing of a predetermined time, which is required until the vacuum arc discharge becomes stable after the turn-on of the vacuum arc discharge. The time required for stabilizing the vacuum arc discharge is variable depending on the cathode material and others, and can be determined in advance by experiments or the like.

In the operation of forming the film by simultaneously using the vapor sources 3 and 3′, control unit CONT determines that the vacuum arc discharge is off when at least one of the current detectors 5 and 5′ in the vapor sources 3 and 3′ does not detect the predetermined discharge current value representing the on state of the discharge. When both the detectors 5 and 5′ detect the predetermined discharge current values, the control unit CONT determines that the vacuum arc discharge is on.

When the control unit CONT determines that the vacuum arc discharge is off, it shuts off the power supply from the power sources PW3, PW4 and PW4′ to the magnetic field forming coils 400, 42 and 42′, and instructs the trigger electrode drive devices D and/or D′ to drive the trigger electrode 35 and/or 35′ to induce the vacuum arc discharge.

When each of the current detectors 5 and 5′ detects the predetermined current value representing the on state of the vacuum arc discharge, the control unit CONT determines that the vacuum arc discharge is on. Upon elapsing of a preset time, which is required until the vacuum arc discharge becomes stable after the turn-on of the vacuum arc discharge in all the vapor source(s) previously kept in the off state, the control unit CONT energizes all the magnetic field forming coils 400, 42 and 42′.

When the vacuum arc discharge becomes off, the detector 5 (5′) cannot detect the discharge current. When the vacuum arc discharge is on, the discharge current can be detected. Based on this, the control unit CONT employs the current value serving as the basis or reference for determination of whether the vacuum arc discharge is on or off. When the current value equal to or greater than the determination reference current value is detected, it is determined that the vacuum arc discharge is on. Otherwise, it is determined that the vacuum arc discharge is off.

In the case where the voltage detectors 50 and 50′ are used for detecting the off state of the discharge, the drive or operation of the vapor sources can be controlled similarly to the case of employing the current detectors 5 and 5′. The voltage detector 50 (50′) detects a rated voltage of the power source PW2 (PW2′) or a voltage close to it when the vacuum arc discharge is off, and detects a voltage of a value smaller than the above voltage when the vacuum arc discharge is on. Based on this, the control unit CONT can employ a voltage value serving as a basis or reference for determination of whether the vacuum arc discharge is on or off. When the detected voltage value is equal to or smaller than this voltage value serving as the determination basis or reference, it is determined that the vacuum arc discharge is on. Otherwise, it is determined that the vacuum arc discharge is off.

According to the vacuum arc vapor deposition apparatus A1, which has been described with reference to FIG. 1, a thin film containing the cathode component material element(s) can be deposited on the deposition target S as follows.

First, the deposition target S is located on the holder 2. Initially, each of the magnetic field forming coils 400, 42 and 42′ is not energized. The exhaust device EX operates to attain the deposition pressure in the container 1 and the ducts 4 and 4′ connected thereto by exhausting a gas therefrom.

If necessary, a bias voltage for attracting the deposition ions is applied from the power source PW1 to the deposition target S on the holder 2. For depositing a uniform thin film, the rotary drive device (not shown) may rotate the holder 2 and thereby the deposition target S during the deposition.

In the above state, the trigger electrodes 35 and/or 35′ in the vapor sources 3 and/or 3′ to be used are brought into contact with the cathodes 31 and/or 31′, and then are spaced therefrom, respectively. Thereby, sparking occurs between the electrode 35 (35′) and the cathode 31 (31′) to trigger the vacuum arc discharge between the anode 34 (34′) and the cathode 31 (31′). This arc discharge heats the cathode material to evaporate the cathode material.

This starts formation of the plasma containing the ionized cathode material in front of the cathode 31 (31′).

During this, the control unit CONT detects the turn-on of the vacuum arc discharge in the vapor source to be used from the information provided from the detector 5 (5′). When the preset time required for stabilizing the vacuum arc discharge elapses thereafter, control unit CONT instructs the coil power sources PW3 and PW4 and/or the power sources PW3 and PW4′ corresponding to the vapor source(s) to be used, and thereby energizes the coils 400 and 42 and/or the coils 400 and 42′.

Thereby, the deflection field(s) formed by the coils 400 and 42 and/or coils 400 and 42′ cause the ionized cathode material(s) produced from the vapor sources 3 and/or 3′ to fly from the separated portion(s) of the ducts 4 and/or 4′ through the common duct end 40 toward the target S on the holder 2. In this operation, the arc discharge may produce rough particles of the cathode material. These rough particles have large mass, and therefore are not led toward the outlet of the common duct end 40 by the deflection field so that the rough particles collide with the inner surface of the duct. In this manner, a good thin film is formed while suppressing flight of the rough particles onto the target S.

During the deposition, when the detector 5 (5′) detects the turn-off of the vacuum arc discharge, the control unit CONT provides an instruction to stop the energizing of the coils 400 and 42 and/or coils 400 and 42′. Thereafter, the coils are energized again when the time required for stabilizing the vacuum arc discharge elapses after the detector 5 (5′) detects turn-on of the vacuum arc discharge caused by the arc ignition.

If the turn-off of the vacuum arc discharge is repeated, and the trigger electrode 35 (35′) performs the arc ignition in response to every turn-off, such particles may be produced that are not preferable in view of the film formation, or may lower the film quality. This particles may occur before the vacuum arc discharge becomes stable. However, even in the above case of the repetitive turn-on and arc ignition, the above structure can restart the film deposition when the vacuum arc discharge is stable, i.e., in such a state that the above unpreferable particles do not reach or substantially do not reach the deposition target S. This can improve the quality of the film.

Since the energizing of the coils immediately restarts upon elapsing of the time required for stabilizing the vacuum arc discharge after the detector 5 (5′) detects the turn-on of the vacuum arc discharge, a long time is not required from the start of deposition to the completion so that the film deposition can be performed efficiently.

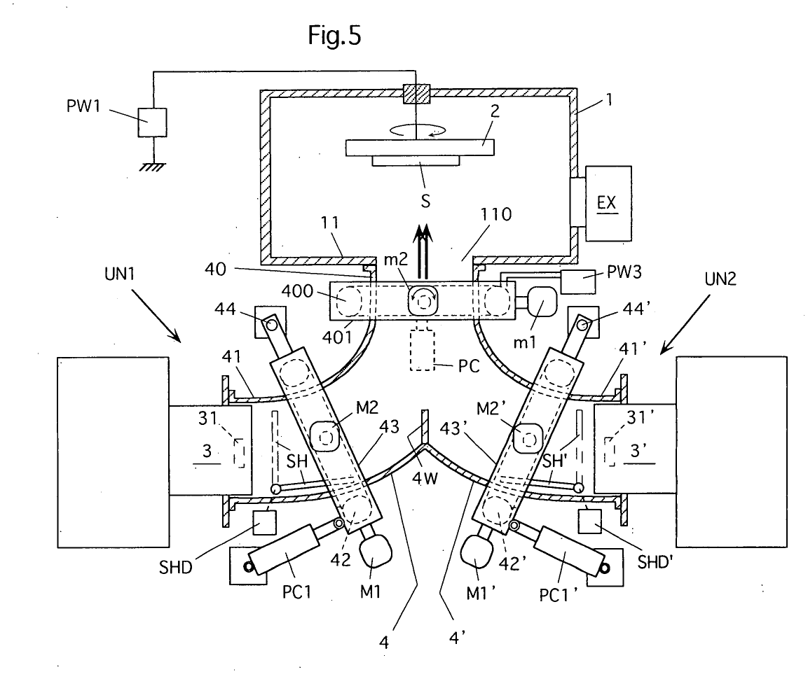

In the foregoing example, the magnetic field forming coils are deenergized for restarting the vacuum arc discharge after the turn-off of the vacuum arc discharge. In stead of or in addition to this manner, as shown in FIG. 5, shutter members SH and SH′ provided in the respective filter ducts 4 and 4′ may be appropriately closed for the above restart operation. Rotary drive devices SHD and SHD′ can selectively locate the shutter members SH and SH′ in positions for closing the passages of the ionized cathode materials and positions retracted therefrom for opening the passages.

The control unit CONT may be configured to provide an instruction controlling the operation of the rotary drive devices SHD and SHD′ to open/close the shutter members. In the foregoing example, when the coil 42 (42′) is to be deenergized, the shutter member SH (SH′) may be located in the closing position in addition to or in instead of such deenergizing. In the foregoing example, when the coil 42 (42′) is to be energized, the shutter member SH (SH′) may be located in the opening position.

In the vacuum arc vapor deposition apparatus A1 described above, the state of arrangement of the magnetic field forming coils 400 and/or 42 with respect to the duct 4 can be adjusted prior to the deposition on the deposition target S such that the ionized cathode material produced from the vapor source 3 may be accurately directed from the common duct end 40 toward the target S on the holder. Thus, one or more of the motors M1 and M2 and the reciprocation drive device PC can adjust the angular position of the magnetic field forming coil 400 around the axis β, the angular position thereof around the axis γ, and/or the position thereof in the direction (vertical direction in FIG. 1) of extension of the duct end 40. Also, one or more of the motors M1 and M2 and the reciprocation drive device PC1 can adjust the angular position of the magnetic field forming coil 42 around the axis β1, the angular position thereof around the axis γ1, and/or the position thereof in the direction of extension of the duct 4.

Also, the state of arrangement of the magnetic field forming coils 400 and/or 42′ with respect to the duct 4′ can be adjusted such that the ionized cathode material produced from the vapor source 3′ may be accurately directed from the common duct end 40 toward the target S on the holder. Thus, one or more of the motors M1 and M2 and the reciprocation drive device PC can adjust the angular position of the magnetic field forming coil 400 around the axis β, the angular position thereof around the axis γ, and/or the position thereof in the direction (vertical direction in FIG. 1) of extension of the duct end 40. Also, one or more of the motors M1′ and M2′ and the reciprocation drive device PC1′ can adjust the angular position of the magnetic field forming coil 42′ around the axis β1′, the angular position thereof around the axis γ1′, and/or the position thereof in the direction of extension of the duct 4′.

Accordingly, in the case of forming a film, e.g., a compound film by using both the vapor sources 3 and 3′, the state of arrangement of one or more of the coils 400, 42 and 42′ may be adjusted with respect to the ducts, and thereby the ionized cathode materials produced from the vapor sources 3 and 3′ may be directed from the separated portions toward the common duct end 40, and may be joined together in the common duct end 40, from which the ionized cathode materials are provided toward the target S on the holder. Thereby, a film of good quality can be formed on the target S.

According to the vacuum arc vapor deposition apparatus A1 described above, the vapor sources 3 and 3′ can be used simultaneously to deposit the compound film made of different materials on the target S. Also, the vapor sources 3 and 3′ can be used alternately and repetitively to deposit the composite film of the fine particle dispersed type and the multi-layer film made of different materials. One of the vapor sources 3 and 3′ can be used to form the base layer on the target S, and thereafter, the other vapor source may be used to form a desired film on the base layer. One of the vapor sources 3 or 3′ may be used to add a different element to the film, which is being formed by the other vapor source 3′ or 3. Only one of the vapor sources can be used to form the film made of the uniform material on the target S.

If necessary, depending on the quality, structure and others of the film to be formed, it is possible to cease and restart the energizing of the magnetic field forming coils 42 and/or 42′ according to predetermined timing. Also, in addition to or instead of such control of the coil energizing, the shutter member SH or SH′ shown in FIG. 5 may be used, e.g., by selectively locating it in the closing and opening positions according to predetermined timing.

For example, the cathode 31 in the vapor source 3 may be formed of a carbon cathode, and the cathode 31′ of the vapor source 3′ may be formed of a metal cathode of tungsten (W), chrome (Cr), titanium (Ti), niobium (Nb), iron (Fe) or the like. Thereby, it is possible to form a DLC (Diamond-Like Carbon) film containing element(s) of such metal added thereto.

Further, a film can be formed in such a manner that another gas plasma is produced in the deposition container 1 by a known manner, and the vapor sources 3 and/or 3′ are also used. For example, plasma of a nitrogen gas may be produced in the deposition container 1, the cathode 31 may be a titanium cathode, and the cathode 31′ may be a carbon cathode or an aluminum cathode so that a TiCN film or a TiAlN film can be formed.

For example, the cathode 31 may be a carbon cathode, and the cathode 31′ may be a metal cathode of tungsten (W), chrome (Cr), niobium (Nb), molybdenum (Mo), iron (Fe) or the like. Thereby, the base layer of the above metal can be formed on the target S, and a DLC film can be formed thereon.

In another specific example, the cathodes 31 and 31′ are formed of a carbon cathode and a tungsten cathode, respectively. In FIG. 1, the coil 42 is arranged such that the coil surface is kept perpendicular to the duct center axis α, and is inclined counterclockwise by 20 degrees around the axis γ1 with respect to the vertical plane. The coil 42′ is arranged such that the coil-surface is kept perpendicular to the duct center axis, and is inclined clockwise by 20 degrees around the axis γ1′ with respect to the vertical plane. Further, the positions of the coils 42 and 42′ in the extension direction of the ducts are kept constant, and the coil 400 is kept horizontal, and is located in a vertically adjusted position. Thereby, such setting is attained that the ionized cathode materials produced from the cathodes are joined in the common duct end 40, and are directed toward the target S. In this state, each of the magnetic field forming coils 42, 42′ and 400 was supplied with a current of 100 [A] to form the deflection magnetic fields, and thereby to evaporate and ionize each cathode with the vacuum arc discharge current of 100 [A]. Thereby, a DLC film containing tungsten added thereto was formed over the target S on the holder 2.

For suppressing such a situation that drift of plasma in the magnetic field formed by the deflection field forming member deteriorates the uniformity in film thickness distribution of the film formed on the surface of the deposition target S, the apparatus may be configured to invert cyclically a direction of a current in at least one of the coils 400, 42 and 42′.

Depending on the quality, structure and others of the film to be formed, the power sources PW2 and/or PW2′ for the vacuum arc discharge may provide pulse outputs, and the control unit CONT may control at least one of the magnitude, pulse width and duty of the pulse voltage. In this case, at least one of the magnitude, pulse width and duty of the pulse voltage may be set via a keyboard (see FIG. 4) connected to the control unit CONT. In any one of the above cases, it can be considered that the power sources PW2 and PW2′ as well as the control unit CONT form the arc power supply device for each vapor source.

For forming the film having high surface smoothness, thickness uniformity and others over a large area, the plurality of vapor sources may be arranged for each of the filter ducts 4 and/or 4′, if necessary. The plurality of vapor sources having cathodes made of the same material may be provided for one filter duct, although this structure is not restrictive.

### INDUSTRIALLY APPLICABILITY

The vacuum arc vapor deposition apparatus of the deflection field type can be used for forming thin films of good quality with good productivity, and particularly for forming thin films on targets or works such as automobile parts, machine parts, tools, dies or the like for the purpose of, e.g., improving at least one of wear resistance, sliding property, corrosion resistance and others.

1. A vacuum arc vapor deposition apparatus of a deflection field type comprising: a plurality of vapor deposition units each including at least one vapor source configured to vaporize and ionize a cathode material by a vacuum arc discharge between a cathode formed of the cathode material and an anode; and a curved filter duct provided with at least one deflection magnetic field forming member providing the ionized cathode material produced from said vapor source toward a holder holding a deposition target for forming a film containing a component element of the cathode material on the deposition target, said curved filter ducts of the plurality of vapor deposition units having duct ends opposed to said holder and formed together to provide a common duct end, and at least one of the vapor sources being arranged on the other end of each of the filter ducts, wherein
said apparatus further comprises a magnetic field forming member adjusting device adjusting a state of arrangement of at least one of said deflection magnetic field forming member provided for at least one of the filter ducts of said plurality of vapor deposition units with respect to said filter duct for controlling the magnetic field.

2. The vacuum arc vapor deposition apparatus of the deflection field type according to claim 1, wherein
the deflection magnetic field forming member shared among said plurality of filter ducts is arranged on the duct end opposed to said holder shared among said plurality of filter ducts, and the deflection magnetic field forming members are arranged on the portions of the filter ducts each spaced from the other filter duct(s), respectively.

3. The vacuum arc vapor deposition apparatus of the deflection field type according to claim 2, wherein
said magnetic field forming member adjusting device is provided for each of said deflection magnetic field forming members.

4. The vacuum arc vapor deposition apparatus of the deflection field type according to claim 3, wherein
said magnetic field forming member adjusting device is a device adjusting a position, in the direction of extension of said filter duct, of the deflection magnetic field forming member having the arrangement state to be adjusted by said magnetic field forming member adjusting device and forming a magnetic field in said filter duct, and/or adjusting an angular position of the deflection magnetic field forming member with respect to the duct.

5. The vacuum arc vapor deposition apparatus of the deflection field type according to claim 1, wherein
at least one of said deflection magnetic field forming members is a magnetic field forming coil to be energized by a field formation power supply device to form a deflection magnetic field, and said field formation power supply device is a power supply device cyclically inverting a direction of a current in at least one of said magnetic field forming coils.

6. The vacuum arc vapor deposition apparatus of the deflection field type according to claim 1, wherein
at least one of said deflection magnetic field forming members is a magnetic field forming coil to be energized by a field formation power supply device to form a deflection magnetic field, and said field formation power supply device is a power supply device capable of turning on/off the power supply to each of the magnetic field forming coils independently of the others.

7. The vacuum arc vapor deposition apparatus of the deflection field type according to claim 1, wherein
at least one of said vapor deposition units is provided with a shut-off member being movable between a closing position for shutting off a passage of said ionized cathode material in the filter duct in said vapor deposition unit and an opening position for opening the passage.

8. The vacuum arc vapor deposition apparatus of the deflection field type according to claim 1, wherein
at least the plurality of vapor deposition units to be used simultaneously among the plurality of vapor deposition units are provided with magnetic field forming coils serving as the deflection magnetic field forming members and forming a deflection magnetic field when being energized by a field formation power supply device, and are also provided with detectors detecting on/off of the arc discharge in said vapor sources, and said field formation power supply device is configured to deenergize the magnetic field forming coils of the vapor deposition units to be used simultaneously when at least one of said detectors in the vapor deposition units to be used simultaneously detects ceasing of the arc discharge, and to allow the energizing of the magnetic field forming coils upon elapsing of a time required for attaining the stable arc discharge in all the vapor sources of the vapor deposition units to be used simultaneously after all the detectors in the vapor deposition units to be used simultaneously detected the arc discharge.

9. The vacuum arc vapor deposition apparatus of the deflection field type according to claim 1, wherein
each of said vapor deposition units to be used simultaneously among the plurality of vapor deposition units is provided with a shut-off member being movable between a closing position for shutting off a passage of the ionized cathode material in the filter duct in said vapor deposition unit and an opening position for opening the passage, a drive device selectively driving the shut-off member to the closing position and the opening position, and a detector detecting on/off of the arc discharge in the vapor source, said drive device of the shut-off member in each of the vapor deposition units is configured to operate under control of a control unit, said control unit, in simultaneous use of said plurality of vapor deposition units to be used simultaneously, controls said drive devices such that said shut-off members of the filter ducts of the vapor deposition units to be used simultaneously are located in the closing position when at least one of said detectors in the vapor deposition units to be used simultaneously detects ceasing of the arc discharge, and to locate said shut-off members in said opening position upon elapsing of a time required for attaining the stable arc discharge in all the vapor sources of said vapor deposition units to be used simultaneously after all the detectors in the vapor deposition units to be used simultaneously detected the arc discharge.

10. The vacuum arc vapor deposition apparatus of the deflection field type according to claim 1, wherein
each of said vapor deposition units has an arc power source device applying a voltage across said cathode and said anode of said vapor source to cause arc discharge, a power supply device applying a pulse voltage is employed as at least one of said arc power supply devices, and said power supply device is configured to control at least one of a magnitude of the pulse voltage, a pulse width and a duty.

11. The vacuum arc vapor deposition apparatus of the deflection field type according to claim 1, wherein
at least one of said vapor deposition units is provided with the plurality of vapor sources.
